(19) United States
(12) Patent Application Publication
(10) Pub. No.: US 2010/0037931 A1
(43) Pub. Date: Feb. 18, 2010

(54) Method and Apparatus for Generating Electric Power Using Solar Energy

(76) Inventor: Chin-Kuang Luo, Taichung City (TW)

Correspondence Address: Sunstein Kann Murphy & Timbers LLP, 125 SUMMER STREET, BOSTON, MA, 02110-1618, US

(21) Appl. No.: 12/260,391

(22) Filed: Oct. 29, 2008

(30) Foreign Application Priority Data
Aug. 18, 2008 (TW) 097131414

(51) Int. Cl. H01L 35/00; H01L 35/34

(52) U.S. Cl. 136/201; 136/206

(57) ABSTRACT

In a method and apparatus for generating electric power using solar energy, a solar energy collecting unit collects solar energy to generate a first power. A thermoelectric semiconductor unit generates a second power from heat dissipated by the solar energy collecting unit. A circuit unit is coupled to the solar energy collecting unit and the thermoelectric semiconductor unit for receiving the first power and the second power and for providing a power output obtained from the first power and the second power.

### CROSS-REFERENCE TO RELATED APPLICATION

This application claims priority of Taiwanese Application No. 097131414, filed on Aug. 18, 2008.

### BACKGROUND OF THE INVENTION

1. Field of the Invention

The invention relates to a method and apparatus for generating electric power, more particularly to a method and apparatus for generating electric power using solar energy.

2. Description of the Related Art

Referring to FIG. 1, a conventional concentrator photovoltaic solar cell system 1 is shown to include a concentrator lens 12 and a condenser 13 for concentrating sunlight onto a solar panel 11, and a heat dissipating member 14 in thermal contact with the solar panel 11. In such a configuration, the system 1 can convert sunlight having a wavelength of 0.2 μm˜0.4 μm into electric power with an electric-generating efficiency of about 42%.

However, due to the heat dissipated by the solar panel 11, temperature of the solar panel 11 is relatively high, e.g., 500° C.˜100° C., which can result in damage to the system 1. Therefore, it is necessary to reduce concentrating efficiency of the concentrator lens 12 to deduce temperature of the solar panel 11, which results in a reduction in the electric-generating efficiency.

### SUMMARY OF THE INVENTION

Therefore, an object of the present invention is to provide a method and apparatus for generating electric power using both solar energy and thermal energy that can improve the electric-generating efficiency.

According to one aspect of the present invention, there is provided an apparatus for generating electric power using solar energy. The apparatus comprises:

a solar energy collecting unit including
a solar panel for collecting solar energy to generate a first power, and
a thermal conductor for conducting heat dissipated by the solar panel, the thermal conductor having a first side surface in thermal contact with the solar panel, and a second side surface opposite to the first side surface;

a thermoelectric semiconductor unit including at least one thermoelectric semiconductor device that has a heat-absorbing surface in thermal contact with the second side surface of the thermal conductor, and a heat-radiating surface opposite to the heat-absorbing surface, the thermoelectric semiconductor device generating a second power corresponding to a difference between temperatures of the heat-absorbing surface and the heat-radiating surface; and

a circuit unit coupled to the solar energy collecting unit and the thermoelectric semiconductor unit for receiving the first power and the second power therefrom, and operable so as to provide a power output obtained from the first power and the second power.

According to another aspect of the present invention, there is provided an apparatus for generating electric power using solar energy. The apparatus comprises:

a solar energy collecting unit for collecting solar energy to generate a first power;

a thermoelectric semiconductor unit for generating a second power from heat dissipated by the solar energy collecting unit; and

a circuit unit coupled to the solar energy collecting unit and the thermoelectric semiconductor unit for receiving the first power and the second power and for providing a power output obtained from the first power and the second power.

According to a further aspect of the present invention, there is provided a method of generating electric power using solar energy. The method comprises the steps of:

collecting solar energy through a solar energy collecting unit to generate a first power;

generating a second power from heat dissipated by the solar energy collecting unit through a thermoelectric semiconductor unit; and

providing a power output obtained from the first power and the second power.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic diagram illustrating a conventional concentrator photovoltaic solar cell system;

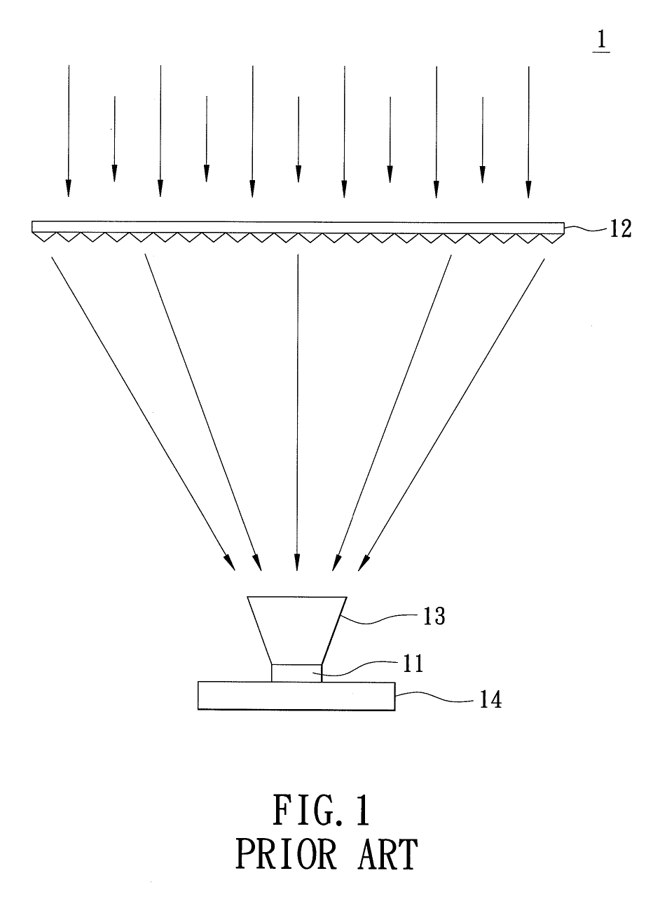

FIG. 2 is a schematic circuit block diagram illustrating the preferred embodiment of an apparatus for generating electric power using solar energy according to the present invention;

FIG. 3 is a partly exploded perspective view showing a solar energy collecting unit and a thermoelectric semiconductor unit of the preferred embodiment; and

FIG. 4 is a schematic sectional view showing a solar panel and a thermal conductor of the solar energy collecting unit and the thermoelectric semiconductor unit of the preferred embodiment.

### DETAILED DESCRIPTION OF THE PREFERRED EMBODIMENT

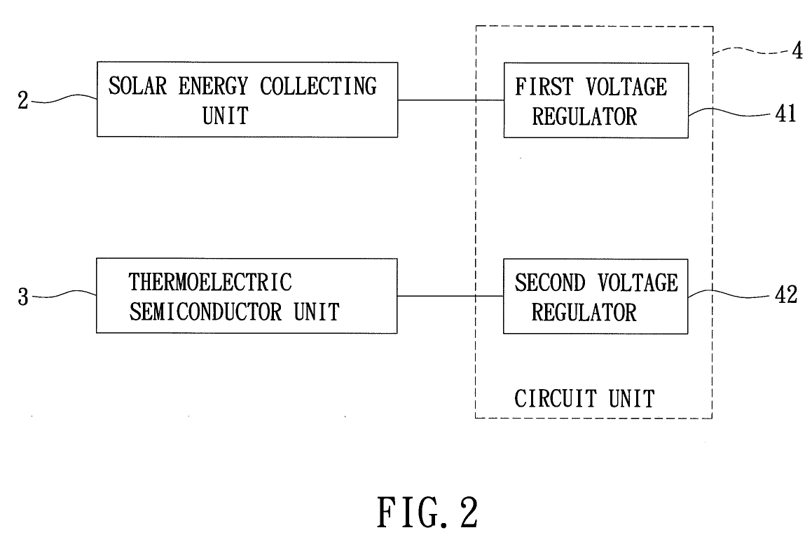

Referring to FIGS. 2 to 4, the preferred embodiment of an apparatus for generating electric power using solar energy according to the present invention is shown to include a solar energy collecting unit 2, a thermoelectric semiconductor unit 3, and a circuit unit 4.

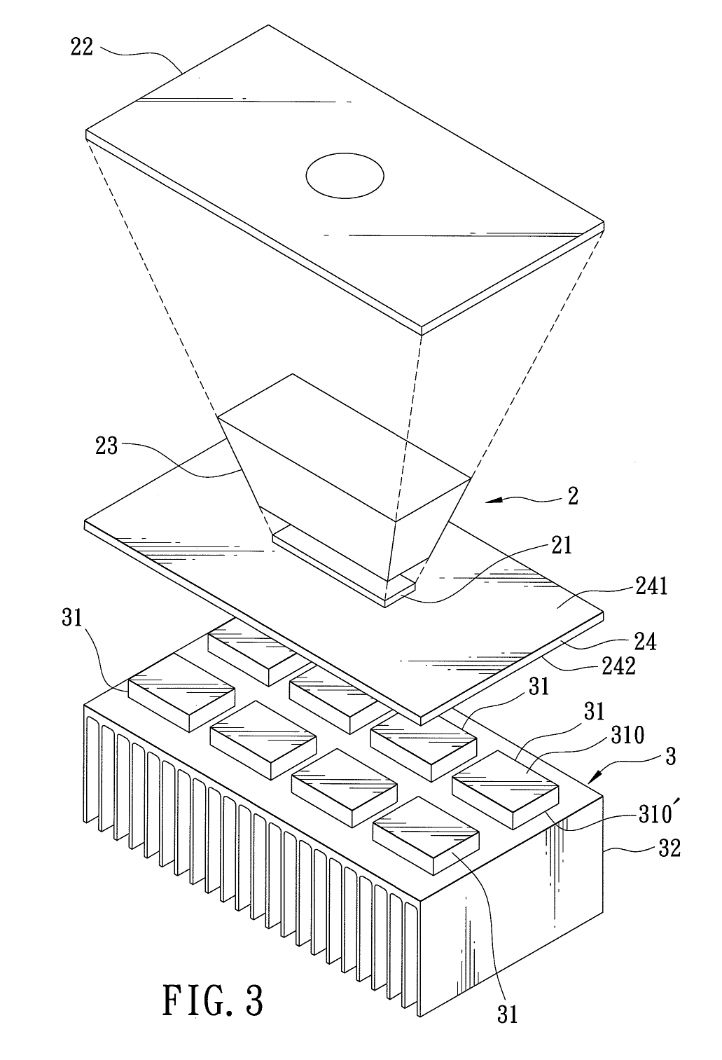

In this embodiment, as shown in FIG. 3, the solar energy collecting unit 2 is a concentrator photovoltaic solar cell system, and includes a solar panel 21, a concentrator lens 22 disposed above the solar panel 21, a condenser 23 disposed between the concentrator lens 22 and the solar panel 21 and attached to the solar panel 21, and a thermal conductor 24, such as a metal plate. As such, sunlight having a wavelength of 0.2 μm˜0.4 μm is concentrated onto the solar panel 21 through the concentrator lens 22 and the condenser 23 such that the solar panel 21 collects solar energy to generate a first power. The thermal conductor 24 has a first side surface 241 in thermal contact with the solar panel 21 for conducting heat dissipated by the solar panel 21, and a second side surface 242 opposite to the first side surface 241.

In this embodiment, the thermoelectric semiconductor unit 3 includes an array of thermoelectric semiconductor devices 31 (see FIG. 3) coupled to each other in series, and a heat dissipating unit 32.

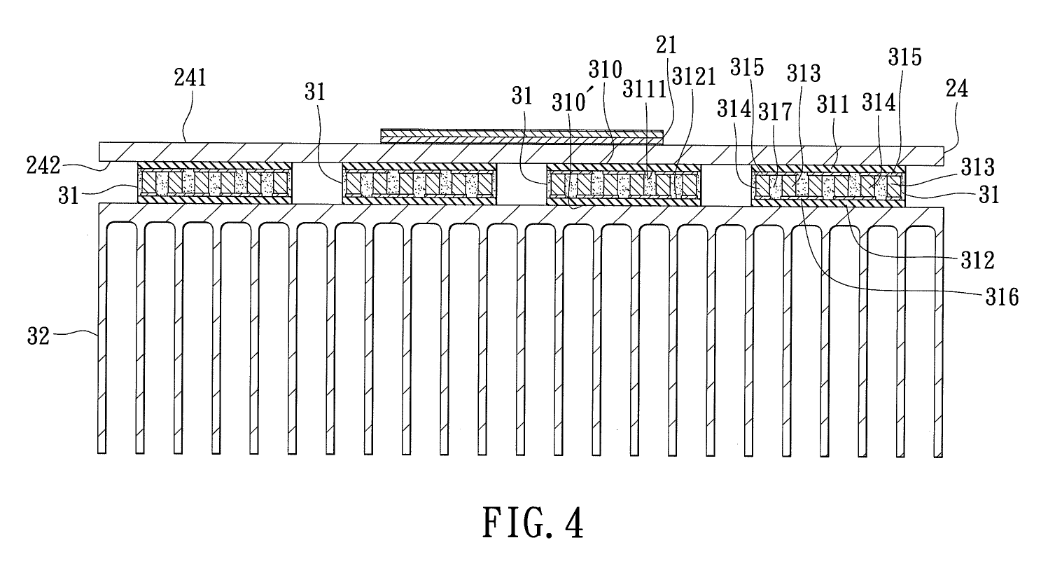

As shown in FIG. 4, each thermoelectric semiconductor device 31, such as a thermoelectric generator, has a heat-absorbing surface 310 in thermal contact with the second side 242 of the thermal conductor 24, and a heat-radiating surface 310′ opposite to the heat-absorbing surface 310. Each thermoelectric semiconductor device 31 generates a second power corresponding to a difference between temperatures of the heat-absorbing surface 310 and the heat-radiating surface 310′. In this embodiment, each thermoelectric semiconductor device 31 includes a first ceramic layer 311, a second ceramic layer 312, a row of first conductive members 315, a row of second conductive members 316, a plurality of alternately arranged P-type and N-type semiconductor elements 314, 313, and a heat insulation material 317. For each thermoelectric semiconductor device 31, the first ceramic layer 311 has an outer surface that serves as the heat-absorbing surface 310, and an inner surface 3111 opposite to the outer surface of the first ceramic layer 311. The second ceramic layer 312 is opposite to the first ceramic layer 311, and has an outer surface that serves as the heat-radiating surface 310′, and an inner surface 3121 opposite to the outer surface of the second ceramic layer 312. The first conductive members 315, such as metal conductors, are attached spacedly to the inner surface 3111 of the first ceramic layer 311. The second conductive members 316, such as metal conductors, are attached spacedly to the inner surface 3121 of the second ceramic layer 312. The P-type and N-type semiconductor elements 314, 313 are disposed between the first and second ceramic layers 311, 312. Each of the P-type and N-type semiconductor elements 314, 313 interconnects electrically a corresponding one of the first conductive members 315 and a corresponding one of the second conductive members 316 to form a serpentine structure so that the P-type and N-type semiconductor elements 314, 313 are connected electrically and alternately to each other in series via the first and second conductive members 315, 316. The heat insulation material 27 is an ammonium phosphate compound in this embodiment, and is filled between the inner surfaces 3111, 3121 of the first and second ceramic layers 311, 312. As a result, the thermoelectric semiconductor unit 2 outputs a sum of the second powers from the thermoelectric semiconductor devices 31.

In this embodiment, the heat dissipating unit 32 includes a heat sink that is in thermal contact with the heat-radiating surface 310′ of each thermoelectric semiconductor device 31. In other embodiments, the heat dissipating unit 32 can include at least one of a heat pipe, a water-cooling device and a fan device.

The circuit unit 4 is coupled to the solar energy collecting unit 2 and the thermoelectric semiconductor unit 3 for receiving the first power and the second powers therefrom, and is operable so as to provide a power output obtained from the first power and the second powers. The power output provided by the circuit unit 4 is adapted to serve as a power source for charging a rechargeable battery (not shown). In this embodiment, the circuit unit 4 includes a first voltage regulator 41 coupled to the solar energy collecting unit 2 for receiving and regulating the first power therefrom, and a second voltage regulator 42 coupled to the thermoelectric semiconductor unit 3 for receiving and regulating the second powers therefrom.

In sum, heat dissipated by the solar panel 21 of the solar energy collecting unit 2 is conducted to the heat-absorbing surfaces 310 of the thermoelectric semiconductor devices 31 through the thermal conductor 24 such that the temperature of the solar panel 21 can be effectively reduced. Furthermore, the heat conducted to the heat-absorbing surfaces 310 of the thermoelectric semiconductor devices 31 is utilized by the thermoelectric semiconductor devices 31 to produce the second powers. Thus, the apparatus of this invention can have an improved electric-generating efficiency compared to the aforementioned prior art.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

1. An apparatus for generating electric power using solar energy, comprising:
a solar energy collecting unit including
a solar panel for collecting solar energy to generate a first power, and
a thermal conductor for conducting heat dissipated by said solar panel, said thermal conductor having a first side surface in thermal contact with said solar panel, and a second side surface opposite to said first side surface;
a thermoelectric semiconductor unit including at least one thermoelectric semiconductor device that has a heat-absorbing surface in thermal contact with said second side surface of said thermal conductor, and a heat-radiating surface opposite to said heat-absorbing surface, said thermoelectric semiconductor device generating a second power corresponding to a difference between temperatures of said heat-absorbing surface and said heat-radiating surface; and
a circuit unit coupled to said solar energy collecting unit and said thermoelectric semiconductor unit for receiving the first power and the second power therefrom, and operable so as to provide a power output obtained from the first power and the second power.

2. The apparatus as claimed in claim 1, wherein said thermoelectric semiconductor device includes
a first ceramic layer having an outer surface that serves as said heat absorbing surface, and an inner surface opposite to said outer surface of said first ceramic layer,
a second ceramic layer opposite to said first ceramic layer and having an outer surface that serves as said heat-radiating surface, and an inner surface opposite to said outer surface of said second ceramic layer,
a row of first conductive members attached spacedly to said inner surface of said first ceramic layer,
a row of second conductive members attached spacedly to said inner surface of said second ceramic layer, and
a plurality of alternately arranged P-type and N-type semiconductor elements disposed between said first and second ceramic layers, each of said P-type and N-type semiconductor elements interconnecting electrically a corresponding one of said first conductive members and a corresponding one of said second conductive members to form a serpentine structure so that said P-type and N type semiconductor elements are connected electrically and alternately to each other in series via said first and second conductive members.

3. The apparatus as claimed in claim 2, wherein said thermoelectric semiconductor device further includes a heat insulation material filled between said inner surfaces of said first and second ceramic layers.

4. The apparatus as claimed in claim 1, wherein said thermal conductor includes a metal plate.

5. The apparatus as claimed in claim 1, wherein said thermoelectric semiconductor unit further includes a heat dissipating unit in thermal contact with said heat-radiating surface of said thermoelectric semiconductor device.

6. The apparatus as claimed in claim 5, wherein said heat dissipating unit includes at least one of a heat sink, a heat pipe, a water-cooling device and a fan device.

7. The apparatus as claimed in claim 1, wherein said circuit unit includes at least one voltage regulator.

8. An apparatus for generating electric power using solar energy, comprising:
a solar energy collecting unit for collecting solar energy to generate a first power;
a thermoelectric semiconductor unit for generating a second power from heat dissipated by said solar energy collecting unit; and
a circuit unit coupled to said solar energy collecting unit and said thermoelectric semiconductor unit for receiving the first power and the second power and for providing a power output obtained from the first power and the second power.

9. (canceled)
